(19) United States
(12) Patent Application Publication
(10) Pub. No.: US 2007/0138593 A1
(43) Pub. Date: Jun. 21, 2007

(54) SEMICONDUCTOR DEVICE THAT IS ADVANTAGEOUS IN MICROFABRICATION AND METHOD OF MANUFACTURING THE SAME

(76) Inventors: Takashi Shigeoka, Yokohama-shi (JP); Shoichi Miyazaki, Yokkaichi-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/558,692

(22) Filed: Nov. 10, 2006

(30) Foreign Application Priority Data
Nov. 11, 2005 (JP) 2005-327600

(51) Int. Cl. H01L 29/00

(52) U.S. Cl. 257/506

(57) ABSTRACT

A semiconductor device includes a semiconductor substrate, a first memory cell transistor, a first select gate transistor, a second memory cell transistor, a second select gate transistor, a contact plug, silicon oxide films, and plasma films which are formed as the same layer as the silicon oxide films and are provided above upper surfaces of the first and the third gate electrodes.

### CROSS-REFERENCE TO RELATED APPLICATIONS

This application is based upon and claims the benefit of priority from prior Japanese Patent Application No. 2005-327600, filed Nov. 11, 2005, the entire contents of which are incorporated herein by reference.

### BACKGROUND OF THE INVENTION

1. Field of the Invention

The present invention relates to a semiconductor device and a method of manufacturing the semiconductor device, and is applied, for example, to a NAND type flash memory.

2. Description of the Related Art

There is conventionally known a NAND type flash memory having a memory cell array structure in which current paths of a plurality of memory cells of a flash memory are connected in series and select gate transistors are provided at both ends of the series-connected current paths. Each of the memory cell transistors is composed of a MOS (Metal Oxide Semiconductor) transistor (hereinafter referred to as “memory cell transistor”) having a dual-gate structure in which a gate insulation film, a floating gate, an inter-gate insulation film and a control gate are successively provided on a semiconductor substrate.

In this NAND type flash memory, a contact with a bit line and a contact with a source line can be shared by the series-connected memory cells, and the memory cell size per 1 bit can greatly be reduced. Thus, the chip size can greatly be reduced, and an increase in capacity can suitably be achieved. In recent years, there has been a strong demand for a greater capacity (on the order of gigabits) and a finer structure of the NAND type flash memory which is usable as a video data storage medium capable of storing, e.g. a large amount of video data of a digital camera, which has steadily been increasing.

In the prior art, however, in the area between select gate transistors for contact with the above-mentioned bit line, there exist a side-wall insulation film, barrier SiN and a residual insulation film which becomes a spacer for neighboring transistors. A bit line contact is provided by making use of a part excluding the area occupied by these films. Thus, the contact is provided by enlarging the area between the select gate transistors.

### BRIEF SUMMARY OF THE INVENTION

According to an aspect of the present invention, there is provided a semiconductor device comprising: a semiconductor substrate including an element region which is partitioned by element isolation films; a first memory cell transistor including a first electrode provided above the semiconductor substrate in the element region; a first select gate transistor including a second electrode provided above the semiconductor substrate in the element region, which selects the first memory cell transistor; a second memory cell transistor including a third electrode provided above the semiconductor substrate in the element region; a second select gate transistor including a fourth electrode provided above the semiconductor substrate in the element region, which selects the second memory cell transistor, the second select gate transistor being adjacent to the first select gate transistor via a diffusion layer formed in a surface of the semiconductor substrate in the element region; a contact plug which is provided on the diffusion layer; silicon oxide films which are provided above side walls of the first and the third gate electrodes; and plasma films which are formed as the same layer as the silicon oxide films and are provided above upper surfaces of the first and the third gate electrodes, upper surfaces of the second and the fourth gate electrodes, above a side surface of the third gate electrode, which is opposed to the fourth gate electrode, above a side surface of the fourth gate electrode, which is opposed to the second gate electrode, and above the element isolation film which is adjacent to the diffusion layer.

According to another aspect of the present invention, there is provided a semiconductor device comprising: a first cell array in which current paths of a plurality of memory cell transistors, which are disposed in a matrix on a semiconductor substrate, are connected in series in a first direction; a second cell array which is disposed to neighbor the first cell array in the first direction; a first select gate transistor which selects the first cell array; a second select gate transistor which selects the second cell array, the second select gate transistor being disposed to neighbor the first select gate transistor and to share one of a source and a drain thereof with the first select gate transistor; a contact plug which is provided on the source or drain that is shared by the first and second select gate transistors; element isolation films which are provided between the first and second select gate transistors, the element isolation films being disposed spaced apart in the semiconductor substrate such that the device isolation films sandwich the contact wiring line in a second direction which is perpendicular to the first direction; side wall films which are provided above side walls of gate electrodes of the memory cell transistors; and barrier layers which are formed as the same layer as the side wall films and are provided above upper surfaces of the gate electrodes of the memory cell transistors, an upper surface of a gate electrode of the first select gate transistor, above a side surface of the gate electrode of the first select gate transistor, which is opposed to the second select gate transistor, an upper surface of a gate electrode of the second select gate transistor, above a side surface of the gate electrode of the second select gate transistor, which is opposed to the first select gate transistor, and above the element isolation film.

According to still another aspect of the present invention, there is provided a method of manufacturing a semiconductor device, comprising: a plurality of element isolation films in a semiconductor substrate in a first direction so as to partition a surface of the semiconductor substrate into a plurality of element regions, a plurality of first gate electrodes of first memory cell transistors formed above the semiconductor substrate in the element regions, a second gate electrodes of first select gate transistors which select the first memory cell transistors, formed above the semiconductor substrate in the element regions, a third gate electrodes of second memory cell transistors formed above the semiconductor substrate in the element regions, fourth gate electrodes which select the second memory cell transistors, formed above the semiconductor substrate in the element regions, wherein each of the second gate electrode is adjacent to one of the fourth gate electrodes via a diffusion layer formed in a surface of the semiconductor substrate, respectively, comprising: forming first silicon oxide films above the semiconductor substrate, above the element isolation films, and above upper surfaces of the first, second, third and fourth gate electrode and side surfaces of the first, second, third and fourth gate electrodes; and forming, by a plasma process, barrier films by nitriding or oxidizing the first silicon oxide films above the upper surfaces of the first, second, third and fourth gate electrodes and above the element isolation film between the second and the fourth gate electrodes, while maintaining the silicon oxide films above the side surfaces of the first and the third gate electrodes.

### BRIEF DESCRIPTION OF THE SEVERAL VIEWS OF THE DRAWING

FIG. 1 is a plan view showing a semiconductor device according to an embodiment of the present invention;

FIG. 2 is a cross-sectional view taken along line II-II in FIG. 1;

FIG. 3 is a cross-sectional view taken along line III-III in FIG. 1;

FIG. 4 is a plan view illustrating a fabrication step of the semiconductor device according the embodiment of the invention;

FIG. 5 is a cross-sectional view illustrating a fabrication step of the semiconductor device according the embodiment of the invention;

FIG. 6 is a cross-sectional view illustrating a fabrication step of the semiconductor device according the embodiment of the invention;

FIG. 7 is a cross-sectional view illustrating a fabrication step of the semiconductor device according the embodiment of the invention;

FIG. 8 is a cross-sectional view illustrating a fabrication step of the semiconductor device according the embodiment of the invention;

FIG. 9 is a cross-sectional view illustrating a fabrication step of the semiconductor device according the embodiment of the invention;

FIG. 10 is a cross-sectional view illustrating a fabrication step of the semiconductor device according the embodiment of the invention;

FIG. 11 is a cross-sectional view illustrating a fabrication step of the semiconductor device according the embodiment of the invention;

FIG. 12 is a cross-sectional view illustrating a fabrication step of the semiconductor device according the embodiment of the invention;

FIG. 13 is a cross-sectional view illustrating a fabrication step of the semiconductor device according the embodiment of the invention;

FIG. 14 is a cross-sectional view illustrating a fabrication step of the semiconductor device according the embodiment of the invention;

FIG. 15 is a cross-sectional view illustrating a fabrication step of the semiconductor device according the embodiment of the invention;

FIG. 16 is a cross-sectional view illustrating a fabrication step of the semiconductor device according the embodiment of the invention;

FIG. 17 is a cross-sectional view illustrating a fabrication step of the semiconductor device according the embodiment of the invention;

FIG. 18 is a cross-sectional view illustrating a fabrication step of the semiconductor device according the embodiment of the invention;

FIG. 19 is a cross-sectional view illustrating a fabrication step of the semiconductor device according the embodiment of the invention; and

FIG. 20 is a cross-sectional view illustrating a fabrication step of the semiconductor device according the embodiment of the invention.

### DETAILED DESCRIPTION OF THE INVENTION

An embodiment of the present invention will now be described with reference to the accompanying drawings. In the description below, common parts are denoted by like reference numerals throughout the drawings.

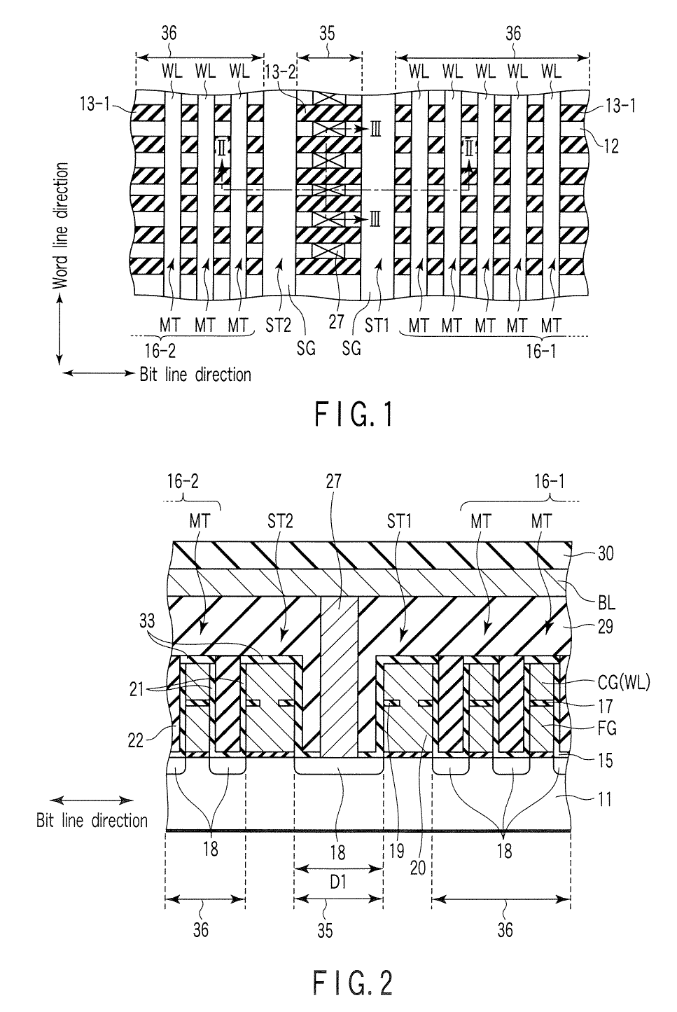

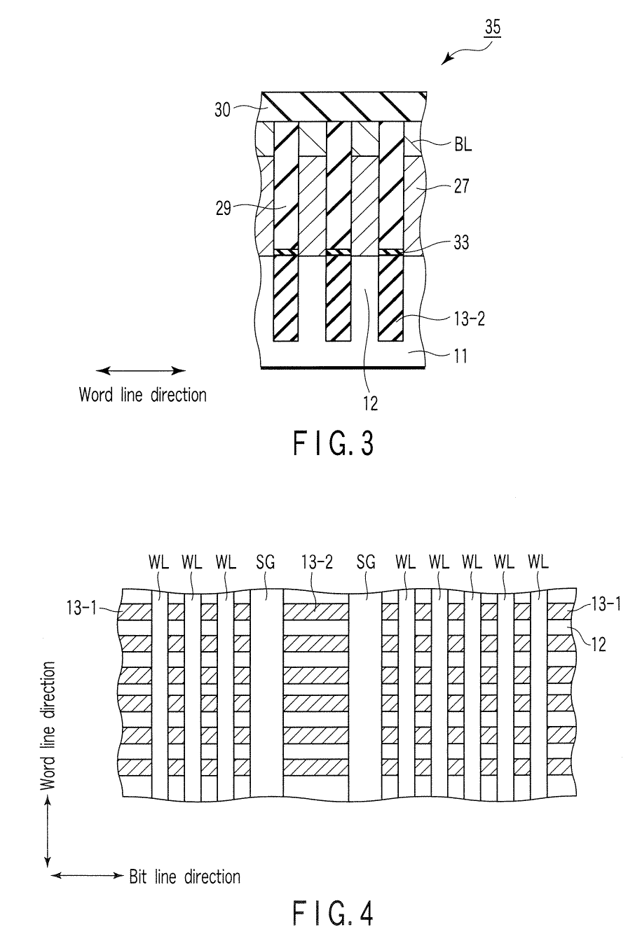

A semiconductor device according to an embodiment of the invention is described with reference to FIG. 1 to FIG. 3. FIG. 1 is a plan view showing the semiconductor device according to the embodiment. FIG. 2 is a cross-sectional view taken along line II-II in FIG. 1. FIG. 3 is a cross-sectional view taken along line III-III in FIG. 1. In this embodiment, a NAND type flash memory is exemplified.

As shown in the Figures, NAND cell arrays 16-1 and 16-2, a select gate transistor ST1 which selects the NAND cell array 16-1, and a select gate transistor ST2 which selects the NAND cell array 16-2 are provided in an element region 12 as active area which is partitioned by element isolation films 13-1 and 13-2 that are buried in a major surface portion of a silicon substrate 11 as a semiconductor substrate. The element isolation films 13-1 and 13-2 are formed of, e.g. a polysilazane (PSZ) film which is an SOG (Spin On Glass) film formed by spin-coating perhydrogenated silazane polymer.

The NAND cell array 16-2 is disposed to neighbor the NAND cell array 16-1 in a bit line direction.

The NAND cell array 16-1, 16-2 comprises a plurality of memory cell transistors MT which have sources/drains 18 as a diffusion layer connected in series in the bit line direction.

Each memory cell transistor MT is provided at an intersection of an associated word line WL and an associated bit line BL (not shown in FIG. 1). The memory cell transistor MT includes a gate insulation film 15 which is provided on the substrate 11, a floating gate electrode FG which is provided on the gate insulation film 15 and isolated in each cell, an inter-gate insulation film 17 which is provided on the floating gate electrode FG, and a control gate electrode CG which is provided on the inter-gate insulation film 17 and is commonly disposed in a word line direction. The floating gate electrode FG, the inter-gate insulation film 17 and the control gate electrode CG constitute a gate electrode of the memory cell transistor.

One of the select gate transistors ST1 and ST2 is disposed to neighbor the other of the select gate transistors ST1 and ST2 in the bit line direction. Each of the select gate transistors ST1 and ST2 includes a gate insulation film 15 which is provided on the substrate 11, a gate electrode 20 which is provided on the gate insulation film 15, and an insulation film 19 which is separated at a central part thereof.

Side wall films 21, which are silicon oxide films, are provided on side walls of the gate electrode of each memory cell transistor MT in a cell region 36, on surface portions of the substrate 11 between the memory cell transistors MT, on surface portions of the substrate 11 between the memory cell transistor MT and select gate transistor ST1, ST2, and on a side wall of the gate electrode of the select gate transistor ST1, ST2, which faces the neighboring memory cell transistor MT. Inter-cell insulation films 22 are provided on the side wall films 21 so as to fill the spaces between the memory cell transistors MT in the bit line direction.

As shown in FIG. 3, barrier films 33 (plasma nitride films) 33 are provided on the element isolation films 13-2 which are provided in the silicon substrate 11 so as to sandwich the select gate transistor ST1, ST2 in the word line direction. The barrier film 33 is not provided on the element isolation film 13-1 in the cell region 36. The barrier film 33 is provided only on the element isolation film 13-2 in an inter-select gate region 35 between the select gates.

Further, barrier films (plasma nitride films) 33 are provided on the gate electrode of each memory cell transistor MT, on the gate electrode of the select gate transistor ST1, ST2, and on the side wall of the gate electrode of the select gate transistor ST1, ST2 in the region 35.

The barrier films 33 are formed by nitriding or high-density oxidation by using a plasma process (to be described later). The barrier films 33 are formed of oxide films including oxygen (O) or nitride films including nitrogen (N). The barrier films 33 are higher than side wall film 21 resistance and barrier to wet etching.

An interlayer insulation film 29 is provided so as to cover the memory cell transistors MT and the select gate transistors ST1, ST2.

In the region 35, a contact wiring line 27 as a contact plug is provided so as to penetrate the interlayer insulation film 29 and barrier film 33 and to reach the source/drain 18 of the select gate transistor ST1, ST2. The contact wiring line 27 is electrically connected to the bit line BL. A distance D1 of the region 35 in the bit line direction is very small. The bit line BL is provided on the interlayer insulation film 29 and the contact wiring line 27. An interlayer insulation film 30 is provided on the bit line BL.

<Manufacturing Method>

Next, a manufacturing method of the semiconductor device according to this embodiment is described by exemplifying the semiconductor device shown in FIG. 1 to FIG. 3.

To start with, as shown in FIG. 4, using well-known fabrication steps, element isolation films 13-1 and 13-2 are formed in the semiconductor substrate 11 of, e.g. silicon, by spin-coating, e.g. perhydrogenated silazane polymer. Then, gate electrodes and sources/drains 18 of memory cell transistors MT and select gate transistors ST1 and ST2 are formed on the substrate 11.

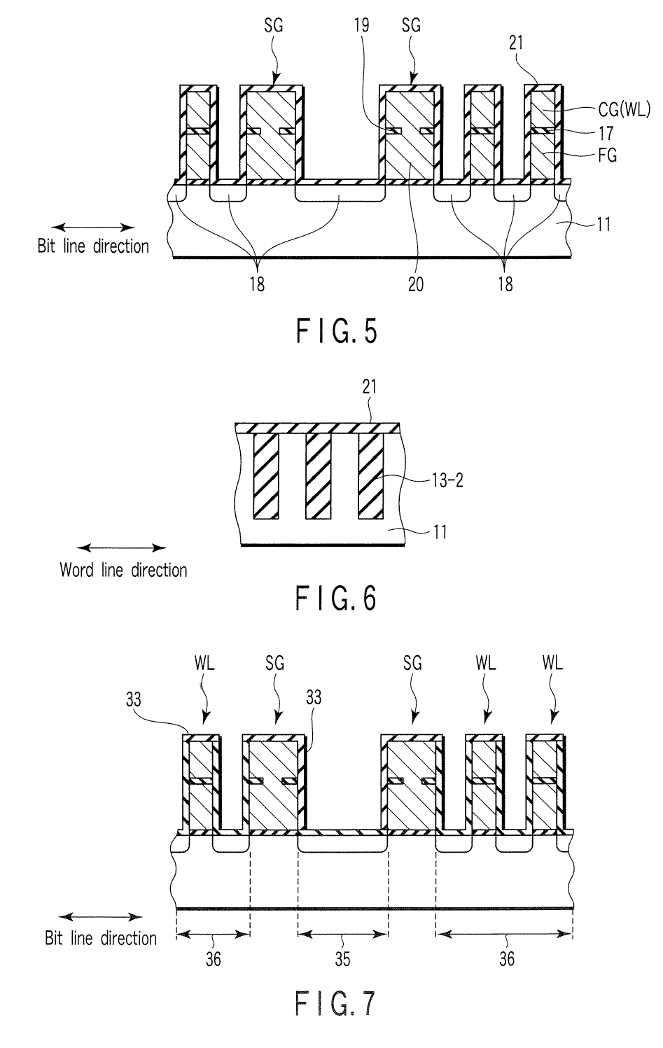

Subsequently, as shown in FIG. 5 and FIG. 6, a side wall film 21, which is formed of a silicon oxide film, is formed by, e.g. thermal oxidation or CVD (Chemical Vapor Deposition) over the upper and side surfaces of the gate electrodes and the sources/drains 18.

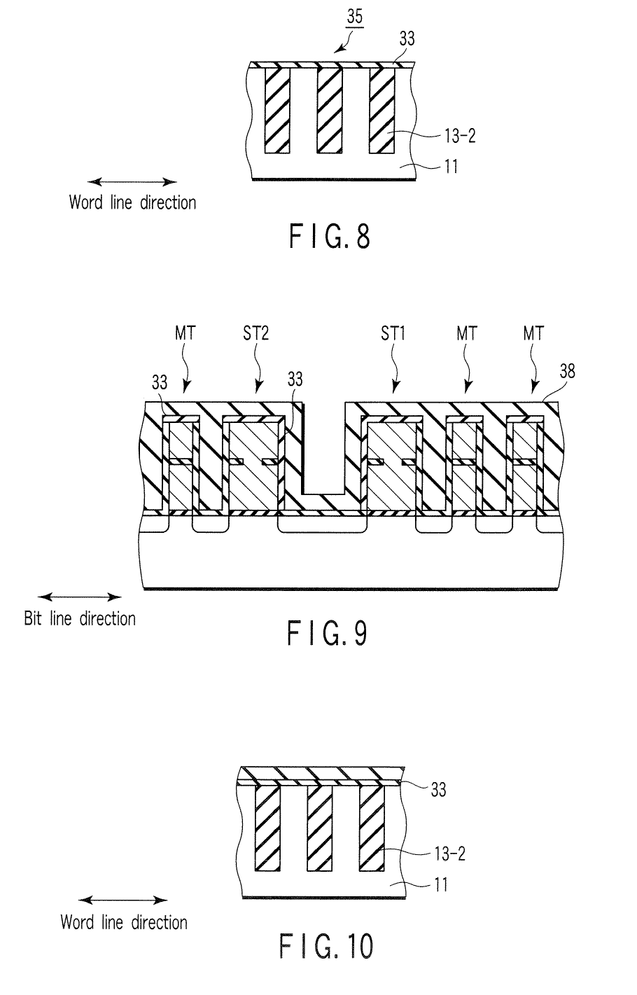

As shown in FIG. 7 and FIG. 8, the side wall film 21 is nitrided by, e.g. a plasma nitriding method, and nitride films are formed. Thus, barrier films 33 are formed.

In the case where a plasma-based film formation process, such as the above-described plasma nitriding, is used, the silicon oxide film is easily nitrided in relatively wide regions, such as upper surfaces of the gate electrodes and the region 35 between the gate electrodes of the select gate transistors ST1 and ST2. Thus, the side wall film 21 is nitrided and the barrier film 33 is formed. On the other hand, in relatively narrow regions such as regions between the gate electrodes of the memory cell transistors MT in the cell region 36, the aspect ratio is so severe that the plasma deactivates. As a result, the side wall film 21 is hardly nitrided. Even if the side wall film 21 is nitrided and the barrier film 33 is formed, the thickness of the formed barrier film 33 is negligibly small.

Similarly, the side wall films 21 on the element isolation film 13-2 and the substrate 11 in the region 35 are nitrided and the barrier films 33 are formed (FIG. 8). On the other hand, the side walls 21 on the element isolation film 13-1 in the cell region 36 are not nitrided since the plasma deactivates, and no barrier film 33 is formed (not shown).

As a result, the barrier films 33 having sufficient film thickness against etching can selectively be formed on the element isolation film 13-2. Thus, in a wet etching process for peeling a spacer insulation film (to be described later), the barrier films 33 can function as etching barriers against etchant. It is possible, therefore, to prevent the element isolation film 13-2 and substrate 11 from retreating, leading to breakage of insulation.

In general, in the case where the etching barrier film is formed by, e.g. CVD, films are formed with uniform thickness regardless of wide or narrow regions. On the other hand, in the plasma process, the amount of nitriding in regions between the cells can be reduced. Therefore, an increase in dielectric constant between the cells can be prevented. The improvement relating to the dielectric constant between the cells leads to a decrease in speed of data write in the cells. In the present embodiment, however, such a problem is prevented and a spacer insulation film between the select gates can be peeled.

In the fabrication step of the barrier film 33, even if oxygen gas is used in place of the nitrogen gas, similar barrier films 33 can be formed by forming high-density oxide films.

In a subsequent step, as shown in FIG. 9 and FIG. 10, a spacer insulation film (LDD mask) 38, which is formed of, e.g. a TEOS (Tetraethylorthosilicate) film, is formed by, e.g. CVD, so as to cover the gate electrodes. The spacer insulation film 38 becomes an inter-cell insulation film 22 which fills regions between the gates of the memory cell transistors MT, and a spacer for peripheral transistors (not shown). The peripheral transistors are, for instance, high-voltage transistors which are disposed in the vicinity of the NAND type flash memory and transfer write voltages to the memory cell transistors MT.

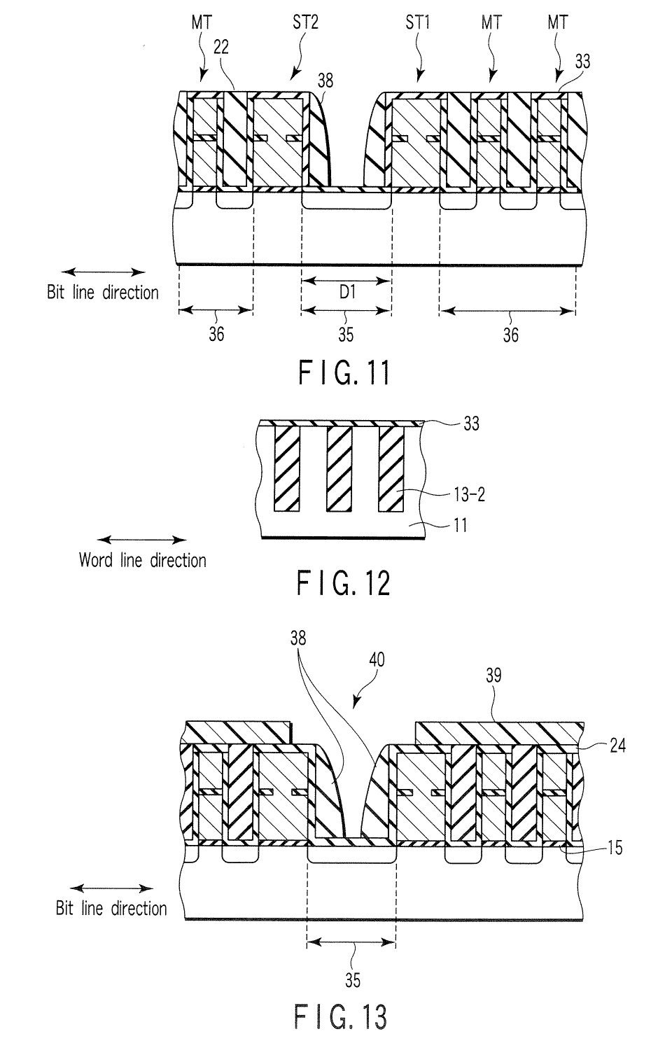

Following the above step, as shown in FIG. 11 and FIG. 12, the spacer insulation film 38 is etched by anisotropic etching, such as RIE, until the surfaces of the barrier films 33 are exposed. By this fabrication step, the spacer insulation film 38 is left between the gate electrodes of the memory cell transistors MT in the cell region 36, and the inter-cell insulation films 22 are formed. In addition, spacers are formed by leaving the spacer insulation film 38 on the side walls of the gate electrodes of the peripheral transistors (not shown).

In this fabrication step, the spacer insulation film 38 is also left on the side walls of the gate electrodes of the select gate transistors ST1 and ST2 in the region 35. The thickness of this spacer insulation film 38 on the substrate 11 is, e.g. about several-ten nm. On the other hand, the distance D1 of the region 35 is very small. Since it is difficult to form a contract wiring line in the remaining space (e.g. several-ten nm), the spacer insulation film 38 needs to be removed.

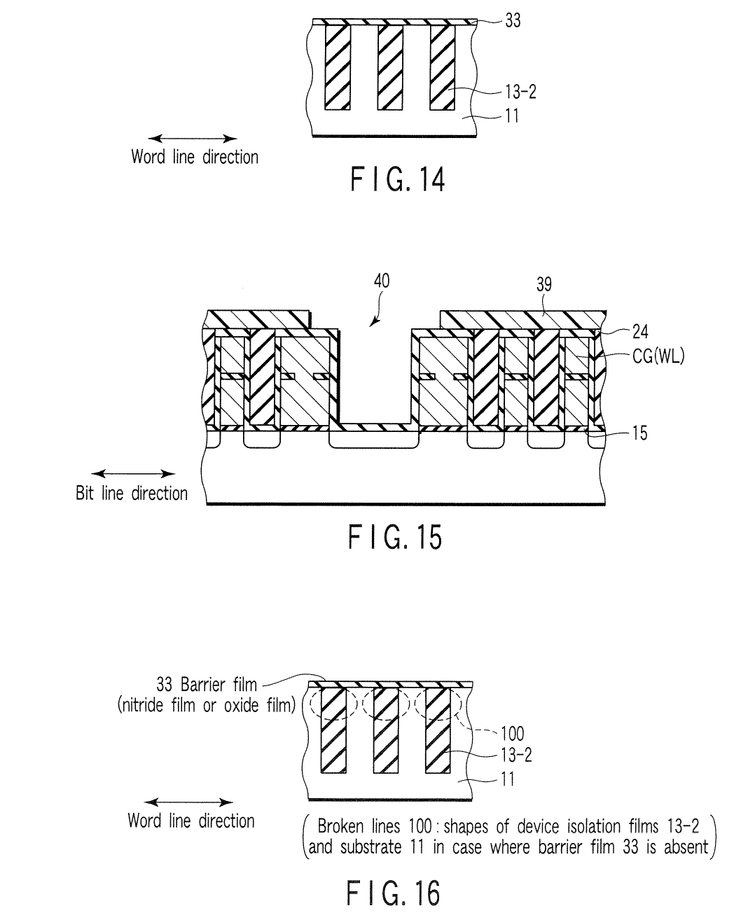

Subsequently, as shown in FIG. 13 and FIG. 14, a photoresist 39 is coated on the barrier films 33, and the photoresist 39 is exposed and developed. Thereby, an opening 40, from which the region 35 is exposed, is formed.

Following the above, as shown in FIG. 15 and FIG. 16, using the photoresist 39 as a mask for etching, the spacer insulation film (TEOS film) 38 remaining in the region 35 is peeled by etching, such as wet etching, using a liquid including at least hydrofluoric acid (HF), such as DHF or BHF.

In the wet etching step, the element isolation film 13-2 in the region 35 is also immersed in the etchant liquid. If a PSZ (polysilazane) film is used as the element isolation film 13-2, the etching rate is too high since the PSZ film has little resistance to wet etching. Consequently, as indicated by broken lines 100 in FIG. 16, the element isolation film 13-2 and substrate 11 greatly retreat not only in the word line direction but also in the bit line direction (not shown), and the element isolation structure may be broken.

However, in the wet etching step of the present embodiment, the etching barrier films 33, which are formed of the nitride films or high-density oxide films by the plasma process, are provided on the element isolation film 13-2. Thus, the barrier films 33 function as barriers against the wet etching. Therefore, the etching selection ratio between the element isolation film (e.g. PSZ film) 13-2 and the spacer insulation film (e.g. TEOS film) 38 can be increased, and the retreat of the element isolation film 13-2 can be prevented.

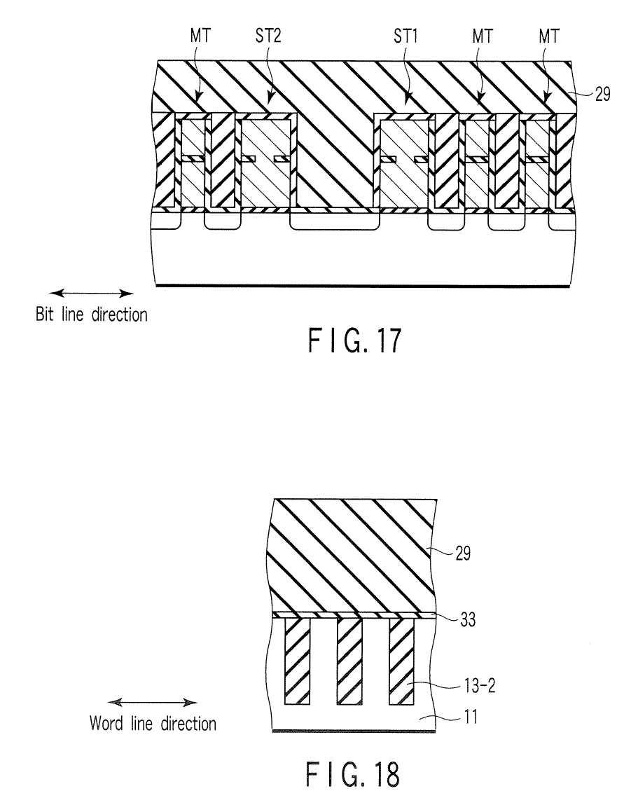

In a following step, as shown in FIG. 17 and FIG. 18, the photoresist 39 is removed by, e.g. an asher.

For example, a silicon oxide film is deposited by, e.g. CVD, so as to cover the select gate transistors ST1 and ST2 and memory cell transistors MT. Thereby, an interlayer insulation film 29 is formed.

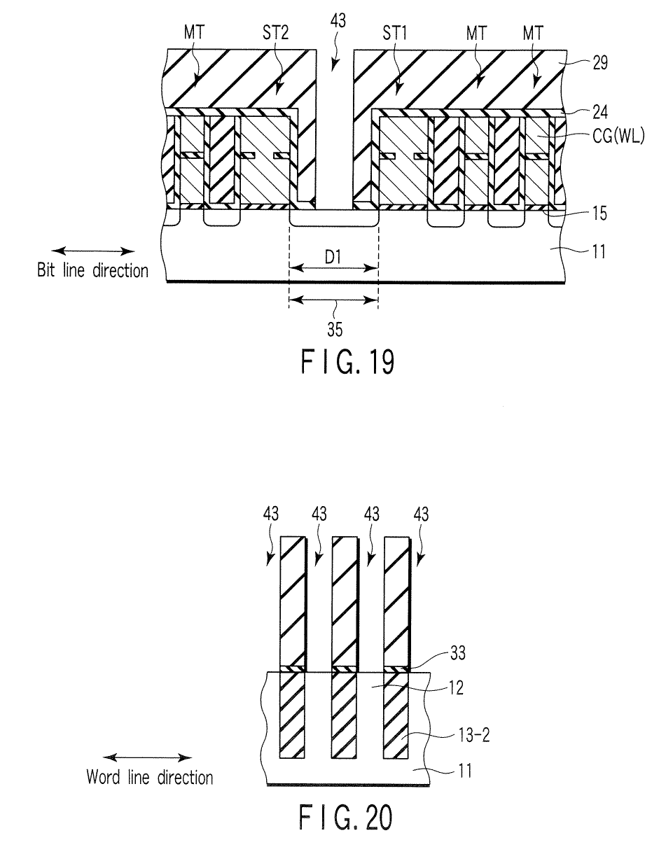

Subsequently, as shown in FIG. 19 and FIG. 20, a trench 43 is formed by anisotropic etching such as RIE. The trench 43 penetrates the interlayer insulation film 29 and barrier film 33 in the region 35, and the surface of the substrate 11 is exposed at a bottom of the trench 43. A metal, such as copper (Cu), is buried in the trench 43 by a well-known fabrication step, and a contact wiring line 27 is formed.

Thereafter, using well-known fabrication steps, a bit line BL and an interlayer insulation film 30 are formed. Thus, the semiconductor device shown in FIG. 1 to FIG. 3 is manufactured.

According to the above-described structure of the present embodiment, the following advantageous effects (1) and (2) are obtained.

(1) Microfabrication is advantageously achieved.

The contact wiring line 27 is provided in the state in which the spacer insulation film 38 is removed. Thus, the distance of the region 35 can be reduced, and microfabrication is advantageously achieved.

(2) Degradation in capacitance characteristics of memory cell transistors MT can be prevented.

In general, a nitride film has a high dielectric constant. If the nitride film is present between the gate electrodes of the memory cell transistors MT, the wiring capacitance value (Yupin value) increases and the cell operation deteriorates. According to the structure of this embodiment, however, in the case where the plasma nitride film is used as the barrier film 33, no nitride film is formed between the gate electrodes of the memory cell transistors MT. Thus, the wiring capacitance value (Yupin value) does not increase, and degradation in capacitance characteristics of the memory cell transistor MT can advantageously be prevented.

Further, according the manufacturing method of the semiconductor device of the embodiment, the following advantageous effects (1) to (4) can be obtained.

(1) Degradation in Capacitance Characteristics of Memory Cell Transistors MT can be Prevented.

As shown in FIG. 7 and FIG. 8, the barrier films 33 are formed by using the plasma-based film formation process such as the plasma nitriding method. Thus, the side wall film 21 is easily nitrided in relatively wide regions, such as upper surfaces of the gate electrodes and the region 35, and the barrier film 33 is formed. However, in relatively narrow regions such as regions between the gate electrodes in the cell region 36, the aspect ratio is so severe that the plasma deactivates. As a result, the side wall film 21 is hardly nitrided, and no barrier film 33 is formed. Even if the barrier film 33 is formed, the thickness of the formed barrier film 33 is negligibly small.

Thus, a nitride film with a high dielectric constant is not formed between the gate electrodes of the memory cell transistors MT, and the wiring capacitance value (Yupin value) does not increase. As a result, degradation in capacitance characteristics of the memory cell transistors MT can advantageously be prevented.

(2) Retreating of the Element Isolation Film 13-2 is Prevented, and Insulation Breakdown of the Element Region 12 can be Prevented.

As shown in FIG. 15 and FIG. 16, in the wet etching step for peeling the spacer insulation film 38 remaining in the region 35, the element isolation film 13-2 in the region 35 is also immersed in the etchant liquid. If a PSZ (polysilazane) film is used as the element isolation film 13-2, the etching rate is too high since the PSZ film has little resistance to wet etching. Consequently, as indicated by broken lines 100 in FIG. 16, the element isolation film 13-2 and substrate 11 greatly retreat not only in the word line direction but also in the bit line direction (not shown), and the element isolation structure may be broken.

However, in the wet etching step of the present embodiment, the etching barrier films 33, which are formed of the nitride films or high-density oxide films by the plasma process, are provided on the element isolation film 13-2. Thus, the barrier films 33 function as barriers against the wet etching. Therefore, the etching selection ratio between the element isolation film (e.g. PSZ film) 13-2 and the spacer insulation film (e.g. TEOS film) 38 can be increased, and the retreat of the element isolation film 13-2 can be prevented.

In this case, the same technique is similarly applicable even if the element isolation film 13-2 is formed of other insulation material with little resistance to wet etching and a high etching rate, and it is possible to enjoy the merit of the high etching selection ratio between the element isolation film 13-2 and spacer insulation film 38. Moreover, the barrier films 33 have the same advantageous effect of etching barriers against dry etching as well as the wet etching.

(3) Microfabrication can Advantageously be Achieved.

As shown in FIG. 19 and FIG. 20, the trench 43 is formed by anisotropic etching. The trench 43 penetrates the interlayer insulation film 29 and etching barrier film 33 in the region 35, and the surface of the substrate 11 is exposed at the bottom of the trench 43. Using a well-known fabrication step, a metal, such as copper (Cu), is buried in the trench 43, and the contact wiring line 27 is formed.

Prior to the step of forming the trench 43, the spacer insulation film 38 is removed from the region 35. Thus, in the step of forming the trench 43, the space for the spacer insulation film 38 can be eliminated. As a result, even if the distance D1 of the region 35 is, e.g. several-ten nm and narrow, the trench 43 can be formed at a desired position, and the contact wiring line 27 can be formed. Therefore, microfabrication can advantageously be achieved.

(4) An Increase in Number of Fabrication Steps can be Suppressed.

As shown in FIG. 7 and FIG. 8, the barrier films 33 can be formed by nitriding (or oxidizing) the side wall film 21. In this case, the plasma-based film formation step is used. Thus, in relatively narrow regions such as regions between the gate electrodes in the cell region 36, the aspect ratio is so severe that the plasma deactivates. As a result, the side wall film 21 is hardly nitrided, and no barrier film 33 is formed. Even if the barrier film 33 is formed, the thickness of the formed barrier film 33 is negligibly small.

Hence, by making use of the deactivation of the plasma itself, the barrier films 33 can be formed simultaneously and selectively on the upper surfaces of the gate electrodes of the memory cell transistors MT and the element isolation film 13-2 of the region 35.

The former barrier film 33 on the upper surface of the gate electrode of the memory cell transistor MT functions as the etching barrier when the trench 43 for forming the contact wiring line 27 is formed, and the reliability for the formation of the trench 43 is improved. The latter barrier film 33 on the element isolation film 13-2 in the region 35 between the select gates functions as the etching barrier in the wet etching step for peeling the spacer insulation film 38, and prevents the element isolation film 13-2 and substrate 11 from retreating, leading to insulation breakdown.

Since the barrier films 33 can be formed simultaneously and selectively at desired positions in a single fabrication step, the increase in number of fabrication steps can be suppressed and the manufacturing cost can advantageously be reduced.

The element isolation film 13-2 is not limited to the single layer of, e.g. PSZ. The element isolation film 13-2 may be formed of two or more layers of at least silicon (Si) and oxygen (O). For example, the element isolation film 13-2 may be formed of a stacked two-layer structure (HDP film/PSZ film) in which an HDP film with a low resistance to wet etching is stacked on a PSZ film with little resistance to wet etching. In this case, too, the HDP film is not peeled in the wet etching step and the PSZ film is prevented from being exposed to the surface. Thus, insulation breakdown of the element region can be prevented.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate including an element region which is partitioned by element isolation films;
a first memory cell transistor including a first electrode provided above the semiconductor substrate in the element region;
a first select gate transistor including a second electrode provided above the semiconductor substrate in the element region, which selects the first memory cell transistor;
a second memory cell transistor including a third electrode provided above the semiconductor substrate in the element region;
a second select gate transistor including a fourth electrode provided above the semiconductor substrate in the element region, which selects the second memory cell transistor, the second select gate transistor being adjacent to the first select gate transistor via a diffusion layer formed in a surface of the semiconductor substrate in the element region;
a contact plug which is provided on the diffusion layer;
silicon oxide films which are provided above side walls of the first and the third gate electrodes; and
plasma films which are formed as the same layer as the silicon oxide films and are provided above upper surfaces of the first and the third gate electrodes, upper surfaces of the second and the fourth gate electrodes, above a side surface of the third gate electrode, which is opposed to the fourth gate electrode, above a side surface of the fourth gate electrode, which is opposed to the second gate electrode, and above the element isolation film which is adjacent to the diffusion layer.

2. The device according to claim 1, wherein the barrier film includes one of a plasma nitride film and a plasma oxide film.

3. The device according to claim 1, wherein the element isolation film includes a polysilazane film which is formed by spin-coating perhydrogenated silazane polymer.

4. The device according to claim 1, wherein each of the first and the third electrodes comprises:
a floating gate electrode which is provided on the semiconductor substrate via a gate insulating films;
an inter-gate insulation film which is provided on the floating gate electrode; and
a control gate electrode which is provided on the inter-gate insulation film.

5. A semiconductor device comprising:
a first cell array in which current paths of a plurality of memory cell transistors, which are disposed in a matrix on a semiconductor substrate, are connected in series in a first direction;
a second cell array which is disposed to neighbor the first cell array in the first direction;
a first select gate transistor which selects the first cell array;
a second select gate transistor which selects the second cell array, the second select gate transistor being disposed to neighbor the first select gate transistor and to share one of a source and a drain thereof with the first select gate transistor;
a contact plug which is provided on the source or drain that is shared by the first and second select gate transistors;
element isolation films which are provided between the first and second select gate transistors, the element isolation films being disposed spaced apart in the semiconductor substrate such that the device isolation films sandwich the contact wiring line in a second direction which is perpendicular to the first direction;
side wall films which are provided above side walls of gate electrodes of the memory cell transistors; and
barrier layers which are formed as the same layer as the side wall films and are provided above upper surfaces of the gate electrodes of the memory cell transistors, an upper surface of a gate electrode of the first select gate transistor, above a side surface of the gate electrode of the first select gate transistor, which is opposed to the second select gate transistor, an upper surface of a gate electrode of the second select gate transistor, above a side surface of the gate electrode of the second select gate transistor, which is opposed to the first select gate transistor, and above the element isolation film.

6. The device according to claim 5, wherein the side wall film includes a silicon oxide film.

7. The device according to claim 5, wherein the barrier film includes one of a plasma nitride film and a plasma oxide film.

8. The device according to claim 5, wherein the element isolation film includes a polysilazane film which is formed by spin-coating perhydrogenated silazane polymer.

9. The element according to claim 5, wherein the memory cell transistor comprises:
a gate insulation film which is provided above the semiconductor substrate;
a floating gate electrode which is provided above the gate insulation film and isolated in each of cells;
an inter-gate insulation film which is provided above the floating gate electrode; and
a control gate electrode which is provided above the inter-gate insulation film.

10. The device according to claim 5, wherein each of the first and second select gate transistors comprises:
a gate insulation film which is provided above the semiconductor substrate;
a gate electrode which is provided above the gate insulation film; and
an insulation film which is separated at a central part thereof.

11. A method of manufacturing a semiconductor device comprising a plurality of element isolation films in a semiconductor substrate in a first direction so as to partition a surface of the semiconductor substrate into a plurality of element regions, a plurality of first gate electrodes of first memory cell transistors formed above the semiconductor substrate in the element regions, a second gate electrodes of first select gate transistors which select the first memory cell transistors, formed above the semiconductor substrate in the element regions, a third gate electrodes of second memory cell transistors formed above the semiconductor substrate in the element regions, fourth gate electrodes which select the second memory cell transistors, formed above the semiconductor substrate in the element regions, wherein each of the second gate electrode is adjacent to one of the fourth gate electrodes via a diffusion layer formed in a surface of the semiconductor substrate, respectively, comprising:
forming first silicon oxide films above the semiconductor substrate, above the element isolation films, and above upper surfaces of the first, second, third and fourth gate electrode and side surfaces of the first, second, third and fourth gate electrodes; and
forming, by a plasma process, barrier films by nitriding or oxidizing the first silicon oxide films above the upper surfaces of the first, second, third and fourth gate electrodes and above the element isolation film between the second and the fourth gate electrodes, while maintaining the silicon oxide films above the side surfaces of the first and the third gate electrodes.

12. The method of manufacturing a semiconductor device, according to claim 11, further comprising:
forming a second silicon oxide film on the first silicon oxide films and the barrier films;
removing the second silicon oxide films between the second and the fourth gate electrodes and from an upper surface of the element isolation films adjacent to the diffusion layer;
forming an interlayer insulation film such that the interlayer insulation film covers the barrier films, second silicon oxide films; and
forming a contact plug which penetrates the interlayer insulation film between the second and the fourth gate electrodes and reaches the diffusion layer.

13. The method of manufacturing a semiconductor device, according to claim 11, wherein said removing the second silicon oxide films includes a step of removing the second silicon oxide films by wet etching.

14. The method of manufacturing a semiconductor device, according to claim 13, wherein said removing step uses a liquid including hydrofluoric acid.

15. The method of manufacturing a semiconductor device, according to claim 11, wherein said the element isolation films are formed by spin-coating perhydrogenated silazane polymer.
